(19) United States
(12) Patent Application Publication
(10) Pub. No.: US 2025/0007477 A1
(43) Pub. Date: Jan. 2, 2025

(54) Active Inductor Peaking Buffer with Output Common Mode Control

(71) Applicant: International Business Machines Corporation, Armonk, NY (US)

(72) Inventors: Dereje Yilma, ROCHESTER, MN (US); Yang You, Austin, TX (US); Ze Zhang, Austin, TX (US); Glen A. Wiedemeier, Austin, TX (US); Chad Andrew Marquart, Austin, TX (US); Daniel Mark Dreps, Georgetown, TX (US)

(21) Appl. No.: 18/341,989

(22) Filed: Jun. 27, 2023

(51) Int. Cl. H03F 3/45; H03F 1/32

(52) U.S. Cl. CPC H03F 3/4565; H03F 1/3211; H03F 3/45183; H03F 2200/372; H03F 2203/45424

(57) ABSTRACT

An integrated circuit includes a semiconductor substrate and integrated circuitry on the semiconductor substrate. The integrated circuitry includes a current-mode logic differential amplifier and a common mode control circuit coupled to the current-mode logic differential amplifier. The common mode control circuit includes a replica circuit replicating a portion of the current-mode logic differential amplifier and a comparator circuit. The comparator circuit is configured to compare a voltage at a sense node in the replica circuit and a reference voltage and to provide to the current-mode logic differential amplifier and, via a feedback loop, to the replica circuit, an output that drives the sense node toward the reference voltage.

### BACKGROUND OF THE INVENTION

This disclosure relates to buffer circuits and, in particular, to an active inductor peaking buffer circuit with output common mode control.

Buffer circuits can be configured to provide a target gain at a desired bandwidth. The bandwidth can be determined from an operating frequency range over which the gain of the buffer circuit is within a desired range. One common type of buffer circuit is a current mode logic (CML) buffer that can be utilized to communicate high-frequency signals, for example, in high-performance computing systems, wireless communication systems, serial data protocols, and other high-speed signaling environments.

In current mode logic, the proper operation of circuits downstream of the buffer circuit can be sensitive to the buffer circuit's output signal amplitude and the common mode voltage of the buffer circuit. In integrated circuitry, the buffer circuit can be sensitive to process, voltage, and/or temperature (PVT) variations, potentially rendering satisfaction of output amplitude and common mode voltage specifications of the buffer circuit difficult. Consequently, the present disclosure appreciates that it would be useful and desirable to provide a buffer circuit having a tightly controlled common mode output voltage regardless of expected PVT variations.

### BRIEF SUMMARY

An integrated circuit includes a semiconductor substrate and integrated circuitry on the semiconductor substrate. The integrated circuitry includes a current-mode logic differential amplifier and a common mode control circuit coupled to the current-mode logic differential amplifier. The common mode control circuit includes a replica circuit replicating a portion of the current-mode logic differential amplifier and a comparator circuit. The comparator circuit is configured to compare a voltage at a sense node in the replica circuit and a reference voltage and to provide to the current-mode logic differential amplifier and, via a feedback loop, to the replica circuit, an output that drives the sense node toward the reference voltage.

### BRIEF DESCRIPTION OF THE SEVERAL VIEWS OF THE DRAWINGS

FIG. 1 is a high-level block diagram of an exemplary integrated circuit in accordance with one embodiment;

FIG. 2 is a more detailed block diagram of an exemplary embodiment of an active inductor peaking buffer circuit with common mode control in the integrated circuit of FIG. 1; and

FIG. 3 is a data flow diagram illustrating a design process.

### DETAILED DESCRIPTION

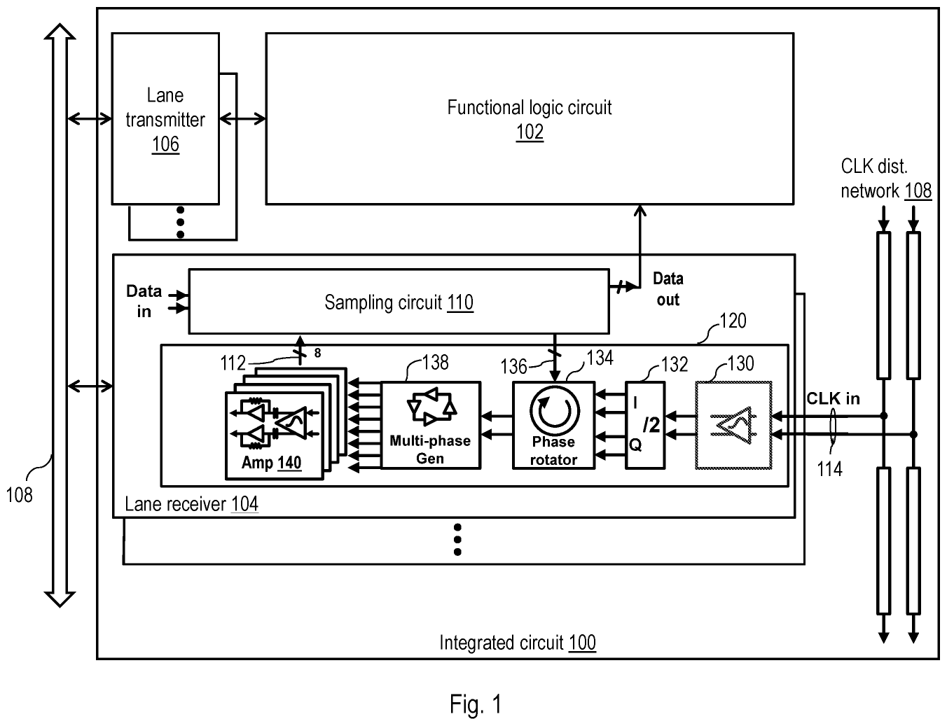

With reference to the figures and with particular reference to FIG. 1, there is illustrated a high-level block diagram of an exemplary integrated circuit 100 including a buffer circuit in accordance with one or more embodiments. In this example, integrated circuit 100 can be, for example, a processor, a programmable logic device, a digital signal processor, a memory controller, a bus or network interface, etc. Integrated circuit 100 includes a functional logic circuit 102 configured to perform one or more functions, such as data processing, data storage, and/or data communication. In addition, integrated circuit 100 includes one or more lane receiver circuits 104 and one or more lane transmitter circuits 106 that respectively receive data from and transmit data to a communication channel 108, such as an interconnect or network.

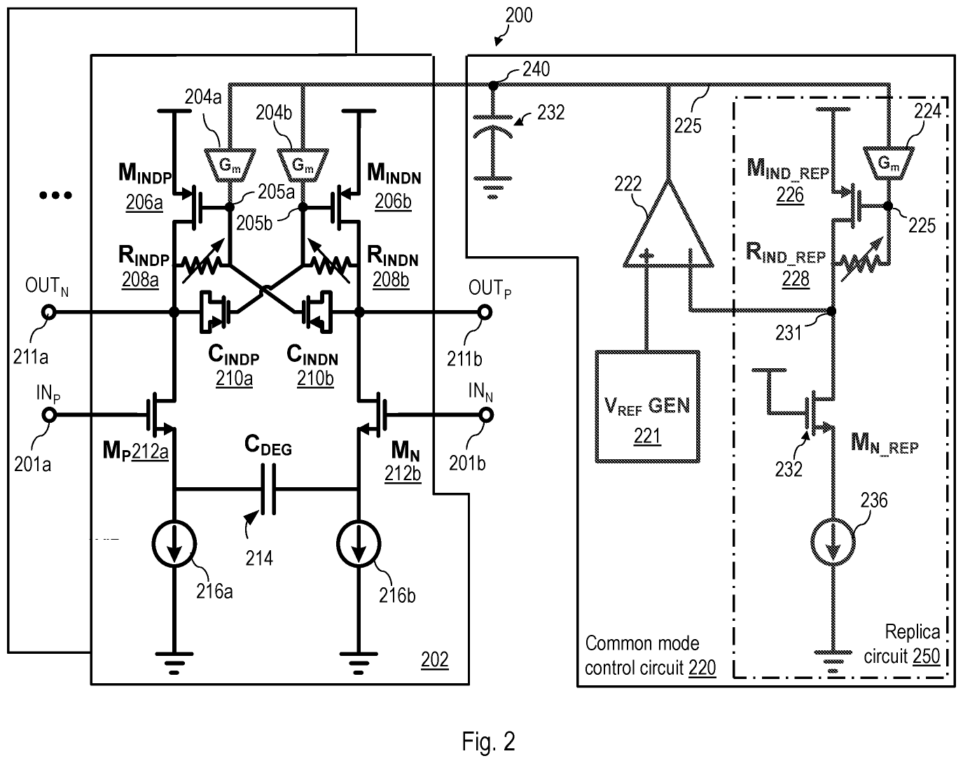

In the example of FIG. 1, lane receiver 104 includes a sampling circuit 110 that samples data on communication channel 108 based on clock signals 112 provided by a clocking circuit 120. Clocking circuit 120 receives a clock signal from clock distribution network 108 at a clock input 114. The clock signal present at clock input 114 is received and buffered by buffer circuit 130, an embodiment of which is described in greater detail below with reference to FIG. 2. Buffer circuit 130 in turn provides a buffered CML-level clock signal to downstream current mode circuitry including a frequency divider 132, a phase rotator 134 (controlled by clock and data recovery (CDR) signals 136 supplied by sampling circuit 110), a multi-phase generator 138, and amplifiers 140. Amplifiers 140 convert eight clock signals of various phases output by multi-phase generator 138 into eight full-rail complementary metal-oxide-semiconductor (CMOS) clock signals 112 provided to sampling circuit 110.

Although FIG. 1 illustrates one exemplary environment in which a buffer circuit 130 may be employed, those skilled in the art will appreciate that such use is merely exemplary and that buffer circuit 130 is not restricted in use to current mode clocking circuits. Rather, buffer circuit 130 can be employed in a wide variety of integrated circuits in which common mode control is useful and/or desirable.

Referring now to FIG. 2, there is depicted a more detailed block diagram of an exemplary embodiment of a buffer circuit 200 with common mode control that can be utilized, for example, to implement buffer circuit 130 in integrated circuit 100 of FIG. 1. Buffer circuit 200 includes one or more current-mode logic differential amplifiers (or drivers) 202, each of which is configured as an active inductor peaking buffer and each of which is coupled to a common mode control circuit 220 at control node 240. In embodiments in which buffer circuit 200 includes two or more amplifiers 202, the amplifiers can be coupled together in parallel. By controlling the voltage at common mode control node 240, common mode control circuit 220 ensures that the common mode voltage at the differential output of each amplifier 202 is tightly controlled within a desired range despite any process, voltage, and/or temperature (PVT) effects.

Each amplifier 202 has a mirrored differential architecture schematically represented by a positive “half” or “side” denoted by component names including the subscript “P” and a negative “half” or “side” denoted by component names including the subscript “N.” In the depicted embodiment, amplifier 202 includes a differential input including a positive input (IN_{P}) node 201a and a negative input (IN_{N}) node 201b. Positive input node 201a is connected to the gate of NMOS input transistor M_{P} 212a, and negative input node 201b is connected to the gate of NMOS input transistor M_{N} 212b. The drain of each of input transistors 212a, 212b is coupled to a respective one of negative output (OUT_{N}) node 211a and positive output (OUT_{P}) node 211b. The source of each of input transistors 212a, 212b is coupled to a respective constant current source 216a, 216b, which is in turn coupled to a lower voltage reference (e.g., ground). Each of constant current sources 216a, 216b can be implemented, for example, with a properly biased current source transistor, in order to provide a tail current that provides input-independent biasing for amplifier 202. The sources of input transistors 212a, 212b are additionally coupled together by a capacitive source degeneration capacitor C_{DEG} 214, which is sized to cause amplifier 202 to amplify a higher frequency portion of the differential input while rejecting the lower frequency (and DC) portion of the differential input.

Amplifier 202 additionally includes inductor transistors (or active inductors) M_{INDP} 206a and M_{INDN} 206b, each of which has a drain coupled to a respective one of output nodes 211a, 211b and a source coupled to an upper voltage reference (V_{DD}). As is known in the art, inclusion of these peaking inductor transistors M_{INDP} 206a and M_{INDN} 206b increases the bandwidth (reduces the propagation delay) of amplifier 202. The drain of each of inductor transistors M_{INDP} 206a and M_{INDN} 206b (and thus a respective one of output nodes 211a, 211b) is respectively coupled to the gate 205b, 205a of the other of inductor transistors M_{INDN} 206b or M_{INDP} 206a. In the embodiment of FIG. 2, this coupling is implemented via respective transistors (e.g., PMOS transistors), which are configured, by having their source and drain tied together, to operate as capacitors C_{INDP} 210a and C_{INDN} 210b. The gate 205a, 205b and drain of each of inductor transistors M_{INDP} 206a and M_{INDN} 206b is also coupled by a variable resistor R_{INDP} 208a or R_{INDN} 208b. The gate 205a, 205b of each of inductor transistors M_{INDP} 206a and M_{INDN} 206b is provided an input current by a respective transconductance circuit (Gₘ) 204a or 204b, which generates a current having a magnitude dependent upon the voltage present at common mode control node 240.

Still referring to FIG. 2, common mode control circuit 220 includes a replica circuit 250 including components selected and coupled together to substantially replicate one “half” or “side” of the differential architecture of amplifier 202. Thus, for example, replica circuit 250 includes a tail current source 236 corresponding to constant current source 216b, a NMOS input transistor M_{N_REP} corresponding to input transistor M_{N} 212b, a sense node 231 corresponding to positive output (OUT_{P}) node 211b, an inductor transistor (active inductor) M_{IND_REP} 226 corresponding to transistor M_{INDN} 206b, a gate-drain resistance R_{IND_REP} 228 corresponding to R_{INDN} 228b, and a Gₘ block 224 corresponding to Gₘ block 204b. In this example, replica circuit 250 omits a capacitor corresponding to capacitor C_{INDN} 210b. Input transistor M_{N_REP} 232 is biased to an active state by connection of its gate to upper voltage reference V_{DD}. The sizes of the components of replica circuit 250 may not be identical to those of the corresponding components of amplifier 202, but can instead be scaled to any desired size.

Common mode control circuit 220 additionally includes a comparator circuit, such as an operational amplifier (op amp) 222, coupled to replica circuit 250 in a feedback configuration. In this example, op amp 222 has a first input coupled to a reference voltage (V_{REF}) generator 221 and a second input coupled to sense node 231 of replica circuit 250. The output of op amp 222 is connected to common mode control node 240, and common mode control node 240 is further coupled by a feedback loop 225 to the input of the Gₘ block 224 within replica circuit 250. Common mode control circuit 220 also includes a capacitor 232 coupled between common mode control node 240 and a clean reference (ground).

In operation, V_{REF} generator 221 provides a constant reference voltage to op amp 222, which sets the voltage of common mode control node 240 based on the closed loop gain of op amp 222 and the difference between the constant reference voltage and the voltage present at the sense node 231 modeling the corresponding amplifier output node 211b. The output voltage of op amp 222 present on common mode control node 240 is converted into a corresponding current by Gₘ block 224. The current produced by Gₘ block 224 is injected into gate node 225 of inductor transistor 226 and develops an I×R voltage drop across the gate-drain path due to the associated resistance R_{IND_REP} 228. As a result, the common mode voltage of sense node 231 is driven to the reference voltage. The voltage of common mode control node 240 is stabilized by capacitor 232, which has the effect of passing only the DC component of the control signal on common mode control node 240 to amplifier(s) 202. Because replica circuit 250 substantially replicates the design and response of amplifier(s) 202, op amp 222 setting the voltage of common mode control node 240 causes Gₘ blocks 204a, 204b of amplifier 202 to likewise inject the appropriate current into gates 205a, 205b to drive the common mode voltage present at output nodes 211a, 211b to the reference common mode voltage.

It should be noted that common mode control circuit 220 can, in some embodiments, be utilized to control the common mode output voltage of multiple amplifiers 202. In such cases, variable resistance R_{IND_REP} 228 of inductor transistor 226 is preferably controlled to account for the aggregate resistance of the active inductors of amplifiers 202 and the targeted operating frequency of amplifiers 202.

Exemplary buffer circuit 200 provides a number of advantages. First, the disclosed buffer circuit 200 is capable of implementing tight control of the common mode voltage at the differential output nodes 211a, 211b of amplifier(s) 202, ensuring that downstream circuits receive a signal having the full voltage swing of amplifier(s) 202. Second, the common mode voltage on differential output nodes 211a, 211b is independent of the gate-source voltage (V_{GS}) of the transistors of amplifier 202. Third, buffer circuit 200 has a fast response time and is suitable for use in high frequency (e.g., multiple GHz) applications. One reason that buffer circuit 200 has such a fast response time is that common mode control circuit 220 does not load input nodes 201a, 201b or output nodes 211a, 211b. Instead, common mode control circuit 220 only loads low frequency gate nodes 205a, 205b. Fourth, the design of buffer circuit 200 employs few components and therefore has reduced complexity, low power dissipation, and requires only a small chip area. As a result, the components of common mode control circuit 220 can be fabricated with larger device sizes to promote tighter control of the common mode output voltage and reduce the impact of process variability on the effectiveness of the feedback control. Fifth, a single common mode control circuit 220 can provide common mode control for multiple amplifiers 202, providing further savings in chip area, power, and complexity. Sixth, amplifier(s) 202 can operate without hindrance even if common mode control circuit 220 is selectively disabled (e.g., to reduce power dissipation).

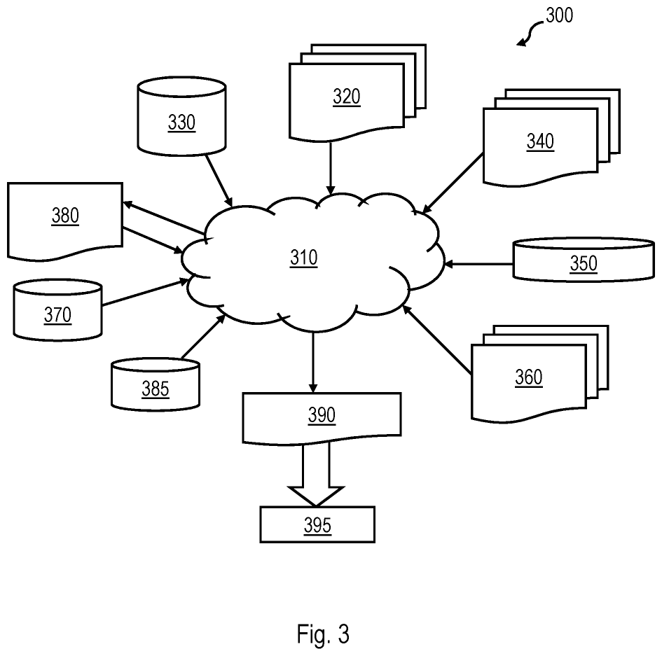

Referring now to FIG. 3, there is depicted a block diagram of an exemplary design flow 300 used for example, in semiconductor IC logic design, simulation, test, layout, and manufacture. Design flow 300 includes processes, machines and/or mechanisms for processing design structures or devices to generate logically or otherwise functionally equivalent representations of the design structures and/or devices described above. The design structures processed and/or generated by design flow 300 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 300 may vary depending on the type of representation being designed. For example, a design flow 300 for building an application specific IC (ASIC) may differ from a design flow 300 for designing a standard component or from a design flow 300 for instantiating the design into a programmable array, for example a programmable gate array (PGA) or a field programmable gate array (FPGA) offered by Altera® Inc. or Xilinx® Inc.

FIG. 3 illustrates multiple such design structures including an input design structure 320 that is preferably processed by a design process 310. Design structure 320 may be a logical simulation design structure generated and processed by design process 310 to produce a logically equivalent functional representation of a hardware device. Design structure 320 may also or alternatively comprise data and/or program instructions that when processed by design process 310, generate a functional representation of the physical structure of a hardware device. Whether representing functional and/or structural design features, design structure 320 may be generated using electronic computer-aided design (ECAD) such as implemented by a core developer/designer. When encoded on a machine-readable data transmission, gate array, or storage medium, design structure 320 may be accessed and processed by one or more hardware and/or software modules within design process 310 to simulate or otherwise functionally represent an electronic component, circuit, electronic or logic module, apparatus, device, or system such as those shown herein. As such, design structure 320 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 310 preferably employs and incorporates hardware and/or software modules for synthesizing, translating, or otherwise processing a design/simulation functional equivalent of the components, circuits, devices, or logic structures shown herein to generate a netlist 380 which may contain design structures such as design structure 320. Netlist 380 may comprise, for example, compiled or otherwise processed data structures representing a list of wires, discrete components, logic gates, control circuits, I/O devices, models, etc. that describes the connections to other elements and circuits in an integrated circuit design. Netlist 380 may be synthesized using an iterative process in which netlist 380 is resynthesized one or more times depending on design specifications and parameters for the device. As with other design structure types described herein, netlist 380 may be recorded on a machine-readable storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, or buffer space.

Design process 310 may include hardware and software modules for processing a variety of input data structure types including netlist 380. Such data structure types may reside, for example, within library elements 330 and include a set of commonly used elements, circuits, and devices, including models, layouts, and symbolic representations, for a given manufacturing technology (e.g., different technology nodes, 10 nm, 20 nm, 30 nm, etc.). The data structure types may further include design specifications 340, characterization data 350, verification data 360, design rules 370, and test data files 385 which may include input test patterns, output test results, and other testing information. Design process 310 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 310 without deviating from the scope and spirit of the invention. Design process 310 may also include modules for performing standard circuit design processes such as timing analysis, verification, design rule checking, place and route operations, etc.

Design process 310 employs and incorporates logic and physical design tools such as HDL compilers and simulation model build tools to process design structure 320 together with some or all of the depicted supporting data structures along with any additional mechanical design or data (if applicable), to generate a second design structure 390. Design structure 390 resides on a storage medium or programmable gate array in a data format used for the exchange of data of mechanical devices and structures (e.g., information stored in an IGES, DXF, Parasolid XT, JT, DRG, or any other suitable format for storing or rendering such mechanical design structures). Similar to design structure 320, design structure 390 preferably comprises one or more files, data structures, or other computer-encoded data or instructions that reside on transmission or data storage media and that when processed by an ECAD system generate a logically or otherwise functionally equivalent form of one or more of the embodiments of the invention shown herein. In one embodiment, design structure 390 may comprise a compiled, executable HDL simulation model that functionally simulates one or more of the devices shown herein.

Design structure 390 may also employ a data format used for the exchange of layout data of integrated circuits and/or symbolic data format (e.g., information stored in a GDSII (GDS2), GL1, OASIS, map files, or any other suitable format for storing such design data structures). Design structure 390 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown herein. Design structure 390 may then proceed to a stage 395 where, for example, design structure 390: proceeds to tape-out, is released to manufacturing, is released to a mask house, is sent to another design house, is sent back to the customer, etc.

As has been described, in at least one embodiment, an integrated circuit includes a semiconductor substrate and integrated circuitry on the semiconductor substrate. The integrated circuitry includes a current-mode logic differential amplifier and a common mode control circuit coupled to the current-mode logic differential amplifier. The common mode control circuit includes a replica circuit replicating a portion of the current-mode logic differential amplifier and a comparator circuit. The comparator circuit is configured to compare a voltage at a sense node in the replica circuit and a reference voltage and to provide to the current-mode logic differential amplifier and, via a feedback loop, to the replica circuit, an output that drives the sense node toward the reference voltage.

While various embodiments have been particularly shown and described, it will be understood by those skilled in the art that various changes in form and detail may be made therein without departing from the spirit and scope of the appended claims and these alternate implementations all fall within the scope of the appended claims. For example, although aspects have been described with respect to a computer system executing program code that directs the functions of the present invention, it should be understood that present invention may alternatively be implemented as a program product including a computer-readable storage device storing program code that can be processed by a processor of a data processing system to cause the data processing system to perform the described functions. The computer-readable storage device can include volatile or non-volatile memory, an optical or magnetic disk, or the like, but excludes non-statutory subject matter, such as propagating signals per se, transmission media per se, and forms of energy per se.

As an example, the program product may include data and/or instructions that when executed or otherwise processed on a data processing system generate a logically, structurally, or otherwise functionally equivalent representation (including a simulation model) of hardware components, circuits, devices, or systems disclosed herein. Such data and/or instructions may include hardware-description language (HDL) design entities or other data structures conforming to and/or compatible with lower-level HDL design languages such as Verilog and VHDL, and/or higher level design languages such as C or C++. Furthermore, the data and/or instructions may also employ a data format used for the exchange of layout data of integrated circuits and/or symbolic data format (e.g. information stored in a GDSII (GDS2), GL1, OASIS, map files, or any other suitable format for storing such design data structures).

The figures described herein and the written description of specific structures and functions are not presented to limit the scope of what Applicants have invented or the scope of the appended claims. Rather, the figures and written description are provided to teach any person skilled in the art to make and use the inventions for which patent protection is sought. Those skilled in the art will appreciate that not all features of a commercial embodiment of the inventions are described or shown for the sake of clarity and understanding. Persons of skill in this art will also appreciate that the development of an actual commercial embodiment incorporating aspects of the present inventions will require numerous implementation-specific decisions to achieve the developer's ultimate goal for the commercial embodiment. Such implementation-specific decisions may include, and likely are not limited to, compliance with system-related, business-related, government-related and other constraints, which may vary by specific implementation, location and from time to time. While a developer's efforts might be complex and time-consuming in an absolute sense, such efforts would be, nevertheless, a routine undertaking for those of skill in this art having benefit of this disclosure. It must be understood that the inventions disclosed and taught herein are susceptible to numerous and various modifications and alternative forms. Lastly, the use of a singular term, such as, but not limited to, “a” is not intended as limiting of the number of items.

What is claimed is:

1. An integrated circuit, comprising:
a semiconductor substrate;
integrated circuitry on the semiconductor substrate, wherein the integrated circuitry includes a buffer circuit including:
a current-mode logic differential amplifier; and
a common mode control circuit coupled to the current-mode logic differential amplifier, wherein the common mode control circuit includes:
a replica circuit replicating a portion of the current-mode logic differential amplifier; and
a comparator circuit configured to compare a voltage at a sense node in the replica circuit and a reference voltage and to provide to the current-mode logic differential amplifier and, via a feedback loop, to the replica circuit, an output that drives the sense node toward the reference voltage.

2. The integrated circuit of claim 1, wherein the current-mode logic differential amplifier comprises an active inductor peaking buffer.

3. The integrated circuit of claim 1, wherein:
the output of the comparator circuit is a voltage indicative of the difference between the voltage at the sense node and the reference voltage;
each of the current-mode logic differential amplifier and the replica circuit includes a respective transconductance circuit that is coupled to receive the output of the comparator.

4. The integrated circuit of claim 3, wherein:
the current-mode logic differential amplifier includes a pair of active inductors each having a respective gate; and
the transconductance circuit in the current-mode logic differential amplifier is coupled to inject current in the gate of one of the pair of active inductors.

5. The integrated circuit of claim 1, wherein:
the buffer circuit includes a plurality of current-mode logic differential amplifiers including the current-mode logic differential amplifier; and
all of the plurality of current-mode logic differential amplifiers are coupled to receive the output of the comparator circuit.

6. The integrated circuit of claim 1, wherein:
the current-mode logic differential amplifier includes a pair of active inductors; and
the replica circuit includes a single active inductor.

7. A design structure tangibly embodied in a machine-readable storage device for designing, manufacturing, or testing an integrated circuit, the design structure comprising:
a buffer circuit including:
a current-mode logic differential amplifier; and
a common mode control circuit coupled to the current-mode logic differential amplifier, wherein the common mode control circuit includes:
a replica circuit replicating a portion of the current-mode logic differential amplifier; and
a comparator circuit configured to compare a voltage at a sense node in the replica circuit and a reference voltage and to provide to the current-mode logic differential amplifier and, via a feedback loop, to the replica circuit, an output that drives the sense node toward the reference voltage.

8. The design structure of claim 7, wherein the current-mode logic differential amplifier comprises an active inductor peaking buffer.

9. The design structure of claim 7, wherein:
the output of the comparator circuit is a voltage indicative of the difference between the voltage at the sense node and the reference voltage;
each of the current-mode logic differential amplifier and the replica circuit includes a respective transconductance circuit that is coupled to receive the output of the comparator.

10. The design structure of claim 9, wherein:
the current-mode logic differential amplifier includes a pair of active inductors each having a respective gate; and
the transconductance circuit in the current-mode logic differential amplifier is coupled to inject current in the gate of one of the pair of active inductors.

11. The design structure of claim 7, wherein:
the buffer circuit includes a plurality of current-mode logic differential amplifiers including the current-mode logic differential amplifier; and
all of the plurality of current-mode logic differential amplifiers are coupled to receive the output of the comparator circuit.

12. The design structure of claim 7, wherein:
the current-mode logic differential amplifier includes a pair of active inductors;
the replica circuit includes a single active inductor.

13. A method, comprising:
providing an integrated circuit, including integrated circuitry on the semiconductor substrate, wherein the integrated circuitry includes a buffer circuit including:
a current-mode logic differential amplifier; and
a common mode control circuit coupled to the current-mode logic differential amplifier, wherein the common mode control circuit includes:
a replica circuit replicating a portion of the current-mode logic differential amplifier; and
a comparator circuit coupled to a sense node in the replica circuit and to current-mode logic differential amplifier; and
comparing, by the comparator circuit, a reference voltage and a voltage at the sense node, and providing to the current-mode logic different amplifier and, via a feedback loop, to the replica circuit, a common mode control output that drives the sense node toward the reference voltage.

14. The method of claim 13, wherein the current-mode logic differential amplifier comprises an active inductor peaking buffer.

15. The method of claim 13, wherein:
the output of the comparator circuit is a voltage indicative of the difference between the voltage at the sense node and the reference voltage;
each of the current-mode logic differential amplifier and the replica circuit includes a respective transconductance circuit that is coupled to receive the output of the comparator.

16. The method of claim 15, wherein:
the current-mode logic differential amplifier includes a pair of active inductors each having a respective gate; and
the method further comprises the transconductance circuit in the current-mode logic differential amplifier injecting current in the gate of one of the pair of active inductors.

17. The method of claim 13, wherein:
the buffer circuit includes a plurality of current-mode logic differential amplifiers including the current-mode logic differential amplifier; and
all of the plurality of current-mode logic differential amplifiers are coupled to receive the output of the comparator circuit.

18. The method of claim 13, wherein:
the current-mode logic differential amplifier includes a pair of active inductors;
the replica circuit includes a single active inductor.
